(19) United States
(12) Patent Application Publication
(10) Pub. No.: US 2013/0147332 A1
(43) Pub. Date: Jun. 13, 2013

(54) HOUSING FOR HARD DISK DRIVE

(71) Applicants: Xiu-Quan HU, Shenzhen City (CN); Lin-Han WU, Shenzhen City (CN); Li HOU, Shenzhen City (CN); Wei WANG, Shenzhen City (CN)

(72) Inventors: Xiu-Quan HU, Shenzhen City (CN); Lin-Han WU, Shenzhen City (CN); Li HOU, Shenzhen City (CN); Wei WANG, Shenzhen City (CN)

(73) Assignees: HON HAI PRECISION INDUSTRY CO., LTD., Tu-Cheng (TW); HONG FU JIN PRECISION INDUSTRY(ShenZhen) CO., LTD., Shenzhen City (CN)

(21) Appl. No.: 13/459,094

(22) Filed: Apr. 28, 2012

(30) Foreign Application Priority Data
Dec. 12, 2011 (CN) 201110411735.X

(51) Int. Cl. H05K 5/03

(52) U.S. Cl. 312/319.2; 312/327

(57) ABSTRACT

An exemplary housing for a hard disk drive includes an enclosure, a bracket slidably mounted in the enclosure, and a door mounted to the bracket. The bracket supports the hard disk drive thereon. The door includes a cover pivotably connected to the bracket, and an operation bracket mounted to the cover. The cover can be rotated to a closed status in which the operation bracket is locked with the enclosure, thereby detachably fixing the cover to the enclosure. The cover can also be rotated to an open status in which the operation bracket is detached from the enclosure, whereby the bracket can be slid out of the enclosure to expose the hard disk drive.

### BACKGROUND

1. Technical Field

The present disclosure relates to device housings, and more particularly, to a housing for receiving a hard disk drive.

2. Description of Related Art

Computers have hard disk drives for storing data. For some kinds of computers such as servers or workstations, a large amount of data is required to be stored. Thus, such kinds of computers may incorporate a multiplicity of hard disk drives therein. Generally, each hard disk drive is received in a housing for protection. Typically, one or more of the hard disk drives are required to be maintained, repaired or replaced after operation of the computer for a long period. In order to access any one of the hard disk drives, the corresponding housing generally incorporates a detachable panel. By loosening screws threadedly engaged in the panel, the panel can be detached from the housing to expose the hard disk drive inside the housing. However, the detachment of the panel from the housing is inconvenient and time-consuming.

What is needed, therefore, is a housing for a hard disk drive which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is an isometric, assembled view of a housing in accordance with an embodiment of the present disclosure, wherein a hard disk drive is received in the housing.

FIG. 2 is an exploded view of FIG. 1.

FIG. 3 shows a bottom, rear view of FIG. 2.

FIG. 4 shows the housing of FIG. 1 partially open, and the hard disk drive partially pulled out from an enclosure of the housing.

FIG. 5 is similar to FIG. 4, but viewing a different aspect.

FIG. 6 is similar to FIG. 5, but showing the housing fully open.

FIG. 7 is an enlarged view of a circled part VII of FIG. 2.

FIG. 8 is an enlarged view of an operation bracket of the housing of FIG. 2.

FIG. 9 is an enlarged view of a circled part IX of FIG. 4.

FIG. 10 is an enlarged view of a circled part X of FIG. 5.

### DETAILED DESCRIPTION

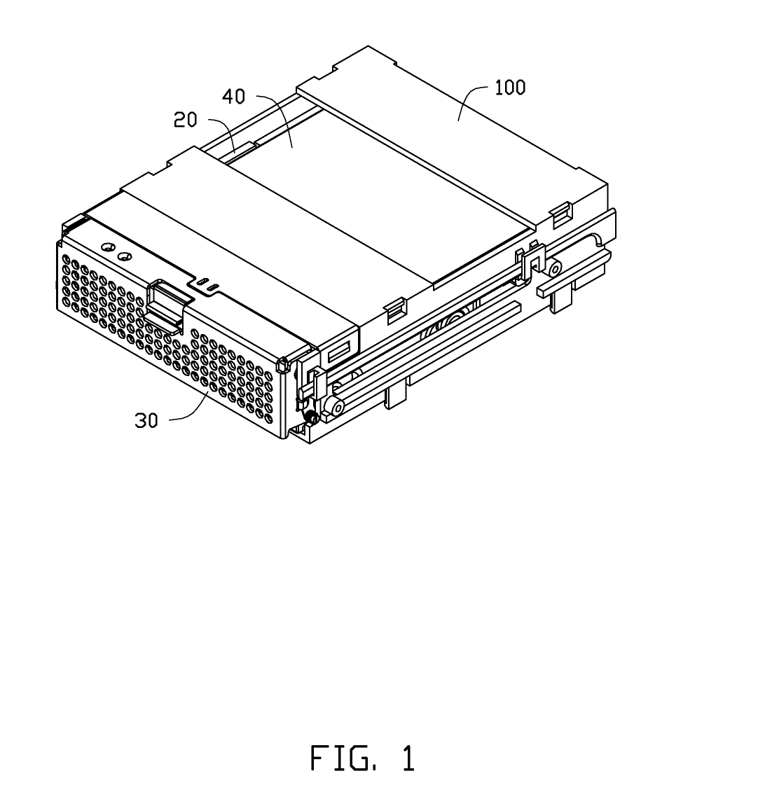

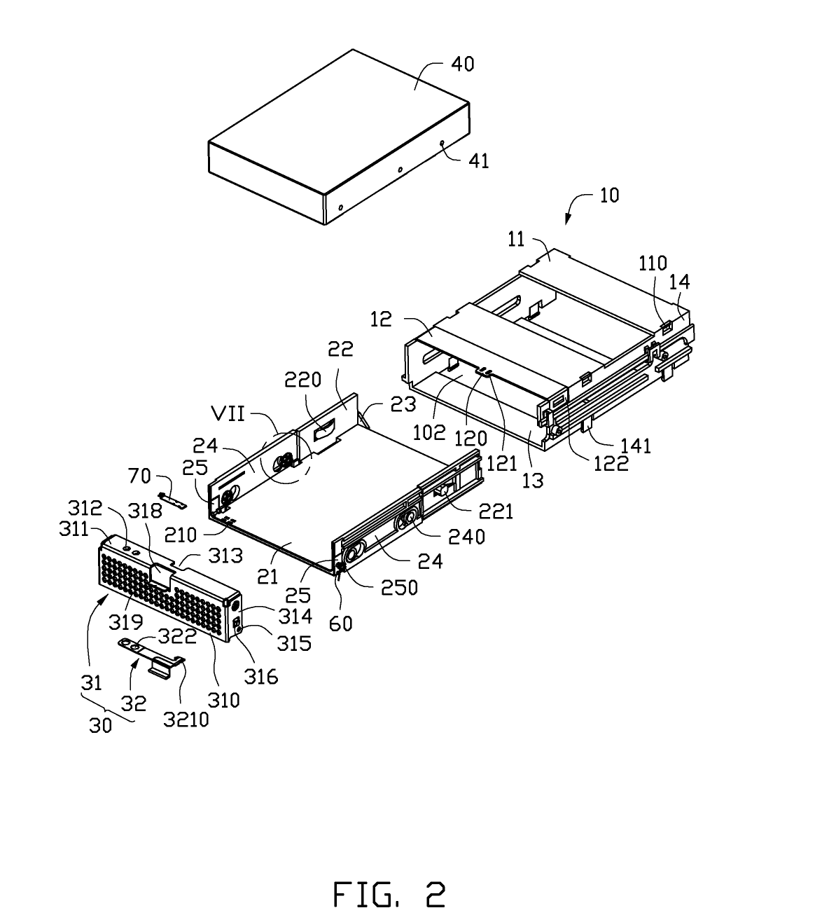

Referring to FIGS. 1-2, a housing 100 for a hard disk drive 40 in accordance with an embodiment of the present disclosure is shown. The housing 100 includes an enclosure 10, a bracket 20 movably mounted in the enclosure 10, and a door 30 rotatably mounted to the enclosure 10.

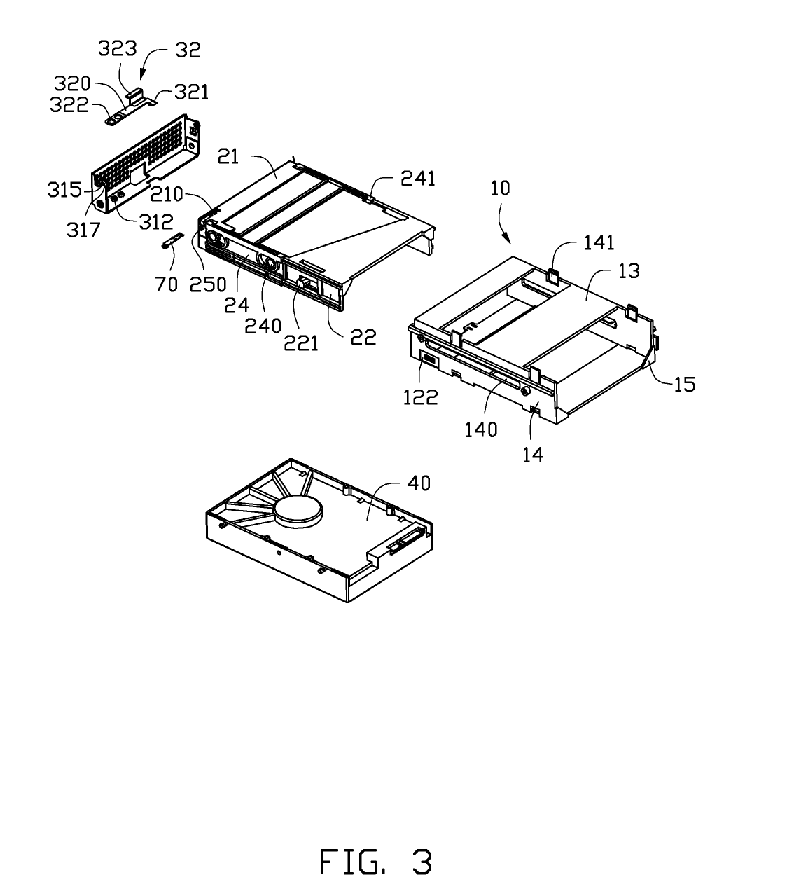

Also referring to FIG. 3, the enclosure 10 includes two side plates 14, two bottom plates 13 connected to bottoms of the two side plates 14, and two top plates 11 connected to tops of the two side plates 14. The two side plates 14 are parallel to each other. The two bottom plates 13 are parallel to the two top plates 11, and perpendicular to the two side plates 14. Each side plate 14 defines a slot 140 along a lengthwise direction thereof. The two top plates 11 are staggered with respect to the two bottom plates 13. Each top plate 11 defines two holes 110 in a right side and a left side thereof, respectively. Each hole 110 extends into a top portion of a corresponding side plate 14. That is to say, each hole 110 is located at a joint of the corresponding side plate 14 and the adjacent top plate 11. Each side plate 14 has two buckles 141 extending downwardly, corresponding to two respective holes 110 of the top plates 11. The buckles 141 of the enclosure 10 can be locked in corresponding holes 110 of a lower enclosure 10 (not shown), and the holes 110 of the enclosure 10 can lockingly retain corresponding buckles 141 of an upper enclosure 10 (not shown). In this way, a plurality of the enclosures 10 can be stacked one on the other.

A retention plate 12 is fixed to the tops of the two side plates 14. The retention plate 12 is located in front of and abuts against a front one of the top plates 11. The retention plate 12 has two ends 122 bent downwardly to engage with the two side plates 14, respectively. The retention plate 12 is detachable from the side plates 14 by disengaging the two ends 122 from the two side plates 14. The retention plate 12 has a tab 120 extending frontward from a front side thereof, and two apertures 121 are defined in the tab 120. A window 102 is defined in a front side of the enclosure 10. The window 102 is surrounded by the retention plate 12, the two side plates 14 and a front one of the bottom plates 13. Two baffle plates 15 are formed on rear ends of the two side plates 14, respectively. Each baffle plate 15 is triangular, and interconnects a corresponding side plate 14 and a rear one of the top plates 11. The two baffle plates 15 prevent the bracket 20 from moving out of the enclosure 10 from a rear side of the enclosure 10.

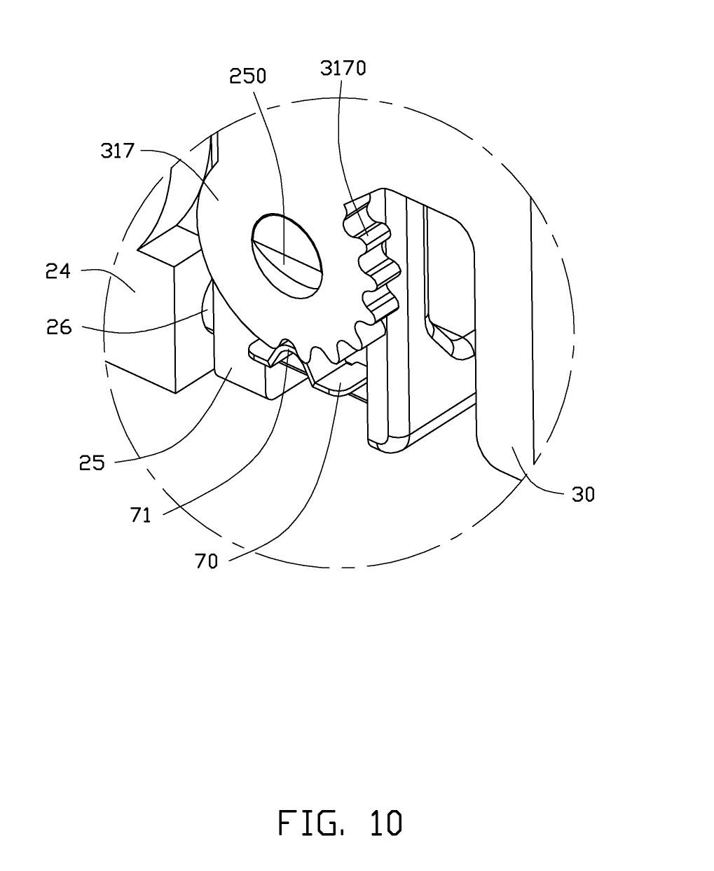

The bracket 20 includes a bottom wall 21, two side walls 22 respectively extending upwardly from a left side and a right side of the bottom wall 21, two retention walls 25 respectively extending upwardly from the left side and the right side of the bottom wall 21, and two rotation walls 24 respectively extending upwardly from the left side and the right side of the bottom wall 21. Each rotation wall 24 interconnects an adjacent side wall 22 and an adjacent retention wall 25. The bottom wall 21 has a width less than that of each bottom plate 13 of the enclosure 10, so that the bracket 20 can be received in the enclosure 10. The bottom wall 21 defines a plurality of through holes 210 adjacent to a front side thereof. In the illustrated embodiment (best seen in FIG. 2), there are four through holes 210. An elastic sheet 70 is fixed to a bottom of the bottom wall 21 by fixing an end of the elastic sheet 70 in the through holes 210. Also referring to FIG. 10, the elastic sheet 70 has an opposite end protruding beyond a left one of the retention walls 25. This opposite end of the elastic sheet 70 has a central portion curved upwardly to form an arc 71. The two side walls 22 are located adjacent to a rear side of the bottom wall 21. The two side walls 22 are perpendicular to the bottom wall 21 and parallel to the retention walls 25. Each side wall 22 has a central portion depressed inwardly to form a curved pressing tab 220. When the hard disk drive 40 is received between the two side walls 22, the two pressing tabs 220 are elastically deformed to press the hard disk drive 40 and position the hard disk drive 40 in the bracket 20. Each side wall 22 forms a protrusion 221 protruding outwardly in a direction away from the pressing tab 220. The protrusion 221 can be received in a corresponding slot 140 to guide the bracket 20 to slide relative to the enclosure 10.

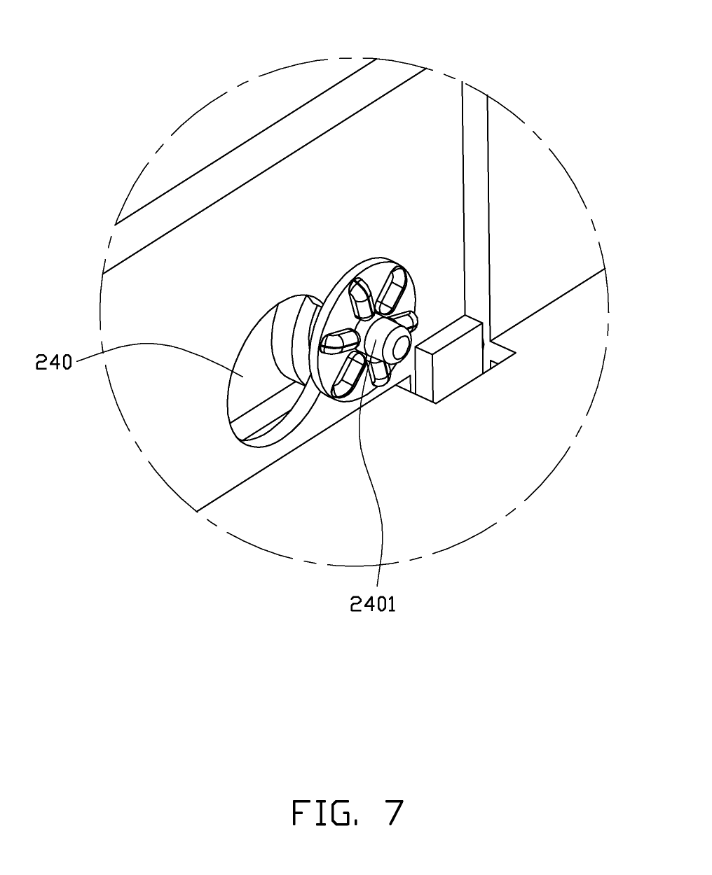

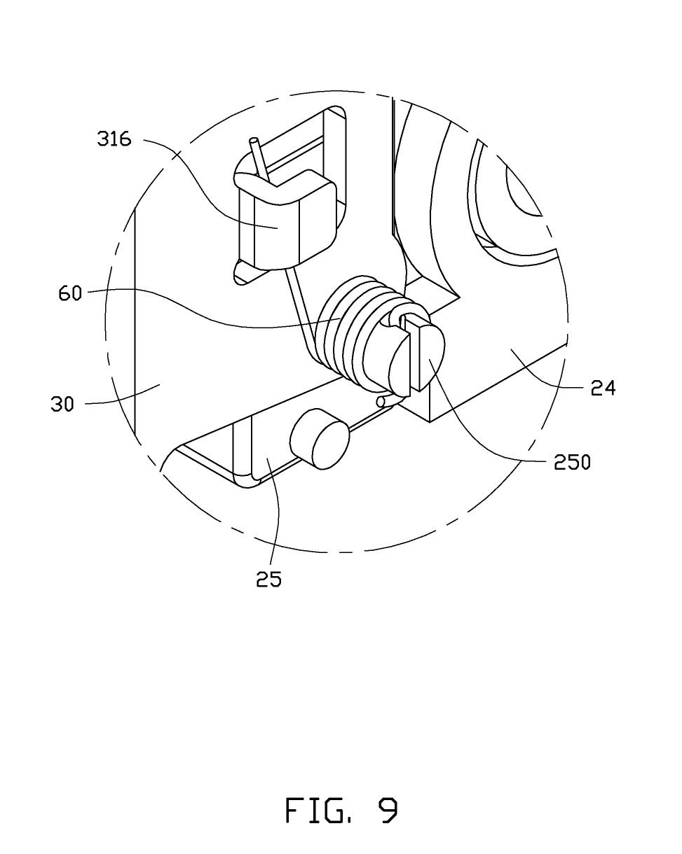

The retention walls 25 are located adjacent to a front side of the bottom wall 21. Each retention wall 25 has a height less than that of each side wall 22. Each retention wall 25 has a pole 250 extending outwardly (see esp. FIG. 9). A right one of the retention walls 25 further has a spring 60 coiled around the pole 250 thereof. The spring 60 has an end fixed in a slot (not labeled) defined in the pole 250, and an opposite end abutting against the door 30 (see also below). Each rotation wall 24 is located between the adjacent retention wall 25 and the adjacent side wall 22. The rotation wall 24 is pivotably connected to the retention wall 25 and the side wall 22, with the axis of rotation of the rotation wall 24 being parallel and adjacent to the bottom wall 21. The pivoting connection of the rotation wall 24 to the retention wall 25 and the side wall 22 may be achieved by extending an axle 26 (see FIG. 10) through the rotation wall 24 into adjacent portions of the retention wall 25 and the side wall 22. The two rotation walls 24 can be rotated outwardly to open statuses in which the rotation walls 24 are parallel to and substantially coplanar with the bottom wall 21. From the open statuses, the two rotation walls 24 can be rotated inwardly to closed statuses in which the rotation walls 24 are perpendicular to the bottom wall 21. Each rotation wall 24 has two through holes 240 defined therein, and two fixing disks 2401 (see FIG. 7) connected on an inner face thereof. An inner post (not labeled) of each fixing disk 2401 can be inserted in a corresponding hole 41 defined in a lateral face of the hard disk drive 40, for fixing the hard disk drive 40 to the rotation walls 24.

A pair of baffle walls 23 are formed at a rear side of the bracket 20. Each baffle wall 23 connects a corresponding side wall 22 and the bottom wall 21. The two baffle walls 23 are used to prevent the hard disk drive 40 from sliding out of the bracket 21 from a rear side of the bracket 21.

The door 30 includes a cover 31, and an operation bracket 32 connected to the cover 31. The cover 31 includes a front panel 310, a top flange 311 extending horizontally from a top side of the front panel 310, and two side flanges 314 extending perpendicularly from a left side and a right side of the front panel 310, respectively. An L-shaped opening 318 is defined in the top flange 311 and the front panel 310, where the top flange 311 joins the front panel 310. The front panel 310 has a confining flange 319 bent frontward from a bottom of the opening 318. The confining flange 319 is parallel to the top flange 311 and perpendicular to the side flanges 314. The top flange 311 defines a rectangular cutout 313 in a rear side thereof to receive the tab 120 of the retention plate 12. The top flange 311 has two collars 312 protruding downwardly from a bottom face thereof. Each side flange 314 defines a hole 315 neighboring a bottom thereof. The poles 250 of the retention walls 25 respectively extend through the holes 315 of the side flanges 314, whereby the cover 31 is pivotably connected to the bracket 20. A right one of the side flanges 314 forms a bent tab 316 (best seen in FIG. 9) adjacent to the hole 315. The opposite end of the spring 60 is engaged with the bent tab 316 to elastically urge the cover 31 to rotate frontward away from the bracket 20. A left one of the side flanges 314 forms a wheel 317 (best seen in FIG. 10) on a bottom thereof. The pole 250 of the left retention wall 25 is inserted in a hole defined in a center of the wheel 317, so that the wheel 317 is rotatable about the pole 250. The wheel 317 has a plurality of teeth 3170 arranged around part of a circumferential periphery thereof. The arc 71 of the elastic sheet 70 can be retained in any one of grooves (not labeled) defined between each two adjacent teeth 3170, to interferingly press the two corresponding adjacent teeth 3170. The interfering engagement between the teeth 3170 of the wheel 317 and the arc 71 of the elastic sheet 70 can slow outward rotation of the cover 31, so that the cover 31 can smoothly rotate even under elastic restoring pressure produced by the spring 60.

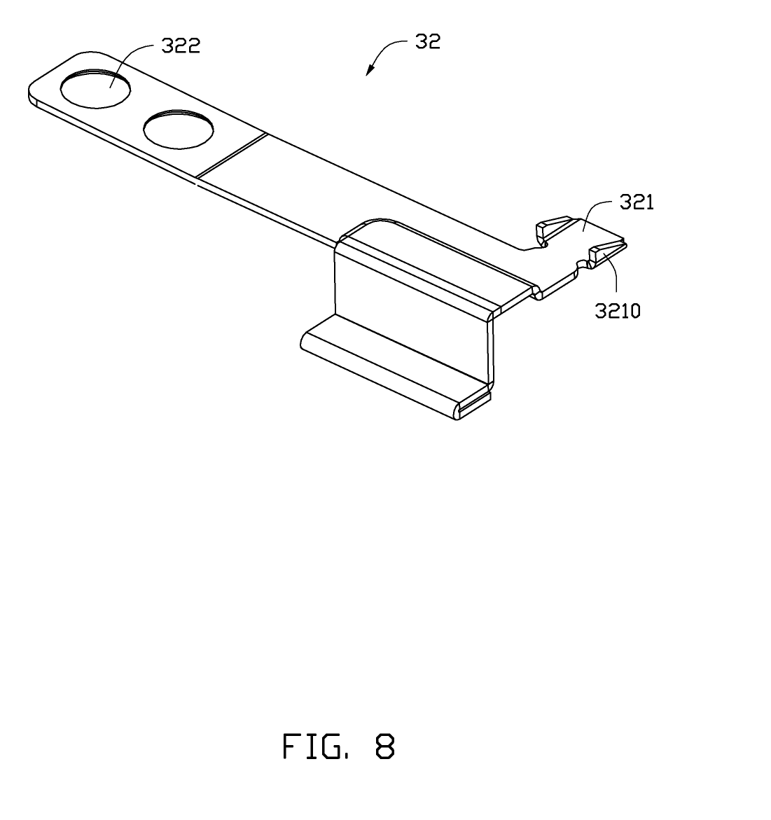

The operation bracket 32 includes a main portion 320, a locking portion 321 extending rearward from a rear side of the main portion 320, and a pressing portion 323 extending downwardly from a front side of the main portion 320. The operation bracket 32 is elastically deformable. The main portion 320 is elongated and defines two holes 322 in a left end thereof. The two collars 312 of the top flange 311 of the cover 31 are engaged in the two holes 322 of the main portion 320 to fix the main portion 320 beneath the top flange 311. The pressing portion 323 is received in the opening 318 of the front panel 310 and protrudes out from a front of the front panel 310. The pressing portion 323 is located higher than the confining flange 319. The locking portion 321 has two protrusions 3210 (see FIG. 8), corresponding to the two apertures 121 of the retention plate 12 of the enclosure 10. The two protrusions 3210 can respectively be inserted into the two apertures 121 of the retention plate 12 to lock the door 30 to the enclosure 10. The pressing portion 323 can be pressed downwardly by an operator to drive the two protrusions 3210 out of the apertures 121 of the retention plate 12, whereby the door 30 can be rotated away from the enclosure 10. The confining flange 319 is used to block the pressing portion 323 when the pressing portion 323 is pressed downwardly, thereby preventing excessive downward movement of the pressing portion 323.

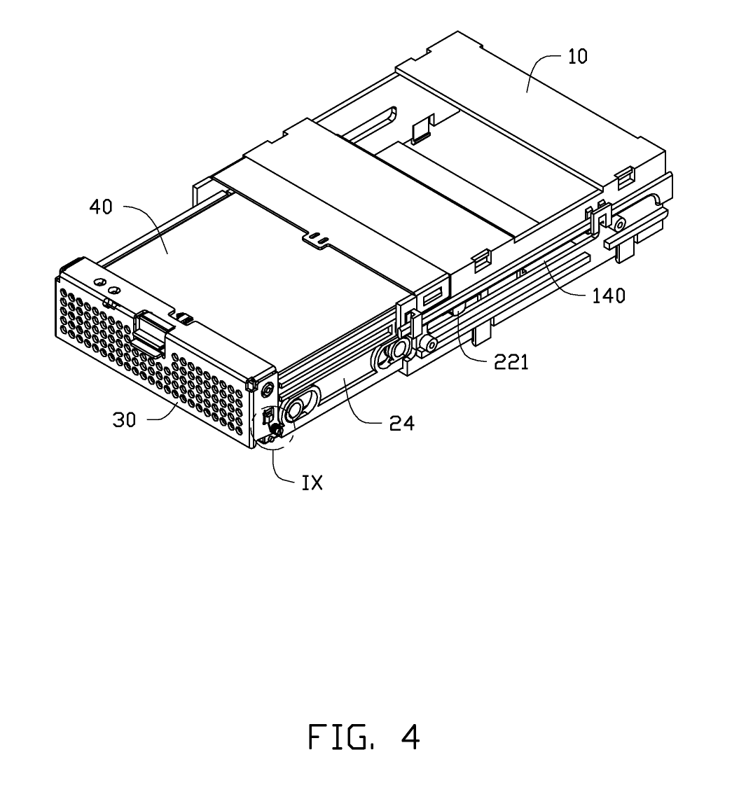

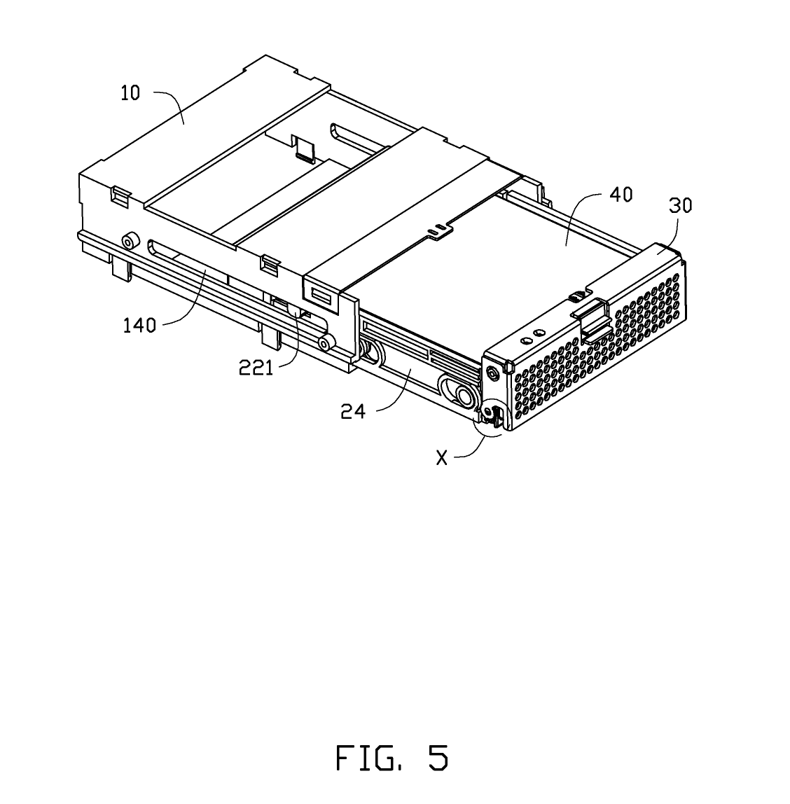

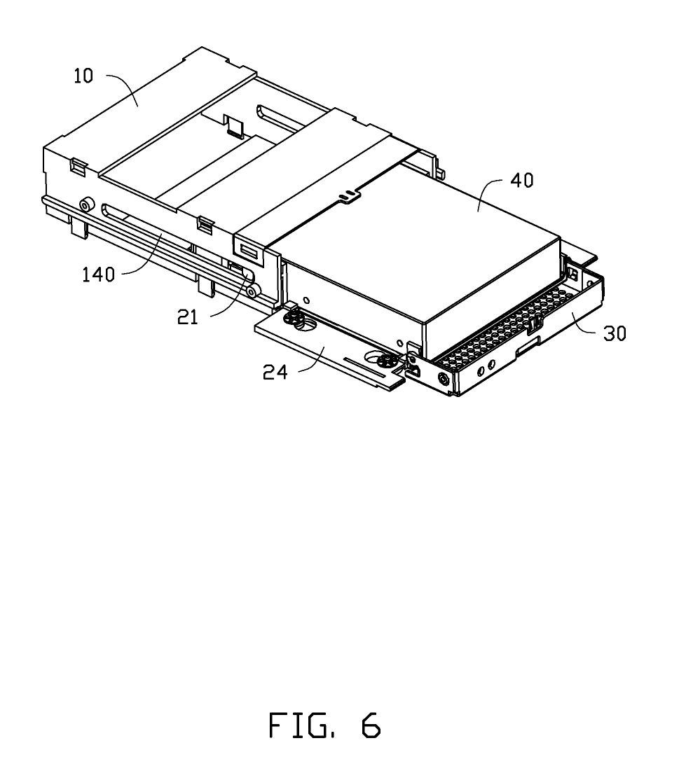

Also referring to FIGS. 4-6, when access to the hard disk drive 40 is required, the pressing portion 323 of the operation bracket 32 is pressed downwardly by the operator, so that the operation bracket 32 is detached from the retention plate 12 of the enclosure 10. The door 30 is automatically rotated outwardly by resilient restoring pressure of the spring 60. The bracket 20 is then slid out from the enclosure 10 by the operator to expose the hard disk drive 40. The two rotation walls 24 of the bracket 20 are rotated outwardly by the operator to the open statuses. The hard disk drive 40 is then easily removed from the bracket 20. Thus, replacement, repair and maintenance of the hard disk drive 40 are convenient and labor-saving.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. A housing for a hard disk drive, comprising:
an enclosure;
a bracket slidably mounted in the enclosure, the bracket configured for supporting the hard disk drive; and
a door comprising a cover pivotably connected to the bracket and an operation bracket mounted to the cover;
wherein the cover is pivotable between a closed status in which the operation bracket is locked with the enclosure to fix the door to the enclosure, and an open status in which the operation bracket is detached from the enclosure; and in the open status, the door is rotatable away from the enclosure and the bracket is slidable out of the enclosure to expose the hard disk drive.

2. The housing of claim 1, wherein the enclosure comprises a spring pressing against the cover to urge the cover to rotate away from the enclosure.

3. The housing of claim 2, wherein the enclosure further comprises a retention plate defining an aperture therein, and the operation bracket comprises a protrusion which is inserted in the aperture to lock the operation bracket with the enclosure.

4. The housing of claim 3, wherein the operation bracket comprises a main portion fixed to the cover, a locking portion extending from the main portion, and a pressing portion formed on the main portion, the protrusion being formed on the locking portion.

5. The housing of claim 4, wherein the pressing portion is pressed downwardly to drive the protrusion away from the aperture of the retention plate, to thereby detach the operation bracket from the enclosure.

6. The housing of claim 4, wherein the cover comprises a front panel and a top flange extending from a top side of the front panel, the main portion of the operation bracket being fixed to the top flange.

7. The housing of claim 6, wherein the cover defines an opening in a joint of the front panel and the top flange, the pressing portion of the operation bracket being exposed within the opening.

8. The housing of claim 6, wherein the cover comprises two side flanges extending from two opposite lateral sides of the front panel, the bracket comprising two poles extending through the two side flanges, respectively.

9. The housing of claim 8, wherein one of the side flanges forms a bent tab thereon, the spring having an end fixed to a corresponding pole of the bracket and an opposite end abutting against the bent tab.

10. The housing of claim 9, wherein the bracket comprises a bottom wall and two retention walls extending upwardly from two opposite sides of the bottom wall, the two poles being formed on the two retention walls, respectively.

11. The housing of claim 10, wherein the bracket comprises an elastic body fixed to the bottom wall, the elastic body having an end protruding beyond a corresponding retention wall, the end of the elastic body forming an arc.

12. The housing of claim 11, wherein the other one of the two side flanges of the cover has a wheel formed on a bottom thereof, the wheel comprising a plurality of teeth distributed on a circumferential periphery thereof, the arc of the bracket interferingly pressing against the teeth of the wheel to slow the rotation of the cover when the cover rotates away from the enclosure.

13. The housing of claim 10, wherein the bracket further comprises two side walls formed on the two opposite sides of the bottom wall, and a pair of rotation walls each connected between an adjacent side wall and an adjacent retention wall.

14. The housing of claim 13, wherein each of the rotation walls is rotatable with respect to the adjacent side wall and adjacent retention wall.

15. The housing of claim 13, wherein each side wall has a part depressed inwardly to form a pressing tab for elastically pressing against the hard disk drive.

16. The housing of claim 13, wherein the bracket further comprises two baffle walls each interconnecting the bottom wall and a corresponding side wall.

17. The housing of claim 13, wherein the enclosure further comprises two side plates and a bottom plate connected between bottoms of the two side plates, the retention plate being fixed on tops of the side plates.

18. The housing of claim 17, wherein each of the side plates defines a slot along a lengthwise direction thereof, each of the side walls having a protrusion received in the slot of a corresponding side plate to guide the bracket to slide relative to the enclosure.

19. The housing of claim 17, wherein the enclosure further comprises a top plate connected between the tops of the side plates, the retention plate being located adjacent to the top plate.

20. The housing of claim 19, wherein the enclosure defines two apertures at joints of the two side plates and the top plate, the enclosure forming two buckles extending downwardly from bottoms of the two side plates, respectively.
